(19) United States
(12) Patent Application Publication
(10) Pub. No.: US 2008/0150154 A1
(43) Pub. Date: Jun. 26, 2008

(54) METHOD FOR FABRICATING A CIRCUIT

(75) Inventors: Harry Hedler, Germering (DE); Roland Irsigler, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/623,581

(22) Filed: Jan. 16, 2007

(30) Foreign Application Priority Data
Dec. 21, 2006 (DE) 10 2006 060 533.0

(51) Int. Cl. H01L 23/52; H01L 21/4763

(52) U.S. Cl. 257/776; 438/622; 257/E23.141; 257/E21.495

(57) ABSTRACT

A method for fabricating a circuit arrangement is provided. One embodiment provides a base layer, whereby the first layer is disposed on the base layer having at least one channel, whereby the first layer is fabricated from an electrically isolating material, whereby the base layer at least partially covers the channel, whereby a second layer is disposed on the first layer, the second layer comprising a recess, the second layer at least partially covering the channel and whereby the recess is at least partially arranged over the channel, whereby the channel and the recess are filled with a liquid, the liquid being cured and an electrical conductor being formed in the channel and in the recess.

### CROSS-REFERENCE TO RELATED APPLICATIONS

This Utility Patent Application claims priority to German Patent Application No. DE 10 2006 060 533.0 filed on Dec. 21, 2006, which is incorporated herein by reference.

### BACKGROUND

The present invention relates to a method for fabricating a circuit arrangement having a first layer including an electrical conductor and an arrangement having a contact layer with a first layer having a channel with an electrical conductor.

In conventional applications, electrical circuits such as memory chips are connected in an electrically conductive manner to a substrate or to further circuits by wire bonds. Moreover, a known method uses flip chip connections by which an electrical circuit is contacted with a substrate or with a further electrical circuit in an electrically conductive manner. In the known methods or in the known arrangements, respectively, a plurality of wires or connection elements are used in order to connect the electrical circuit to a substrate or to a further electrical circuit in an electrically conductive manner.

For these and other reasons, there is a need for the present invention.

### SUMMARY

One embodiment provides a method for fabricating a circuit arrangement having a first layer including an electrical conductor having an electrical contact for an electrical circuit. In one embodiment a base layer is provided, whereby the first layer is disposed on the base layer including at least one channel, whereby the first layer is fabricated from an electrically isolating material, whereby the base layer at least partially covers the channel, whereby a second layer is disposed on the first layer, the second layer comprising a recess, the second layer at least partially covering the channel and whereby the recess is at least partially arranged over the channel, whereby the channel and the recess are filled with a liquid, the liquid being cured and an electrical conductor being formed in the channel and in the recess.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a substrate.

FIG. 2 illustrates a cross-sectional view of the substrate.

FIG. 3 illustrates a substrate with a first layer.

FIG. 4 illustrates a cross-sectional view of the substrate with a first layer.

FIG. 5 illustrates a substrate with a first layer and a second layer.

FIG. 6 is a cross-sectional view of the substrate with the first layer and the second layer.

FIG. 7 illustrates the substrate with the first and the second layer filled with a liquid conductive material.

FIG. 8 is a cross-sectional view of the substrate with the first and the layer filled with the liquid material.

FIG. 9 is a cross-sectional view of the substrate with the first and the second layer having contact balls.

FIG. 10 illustrates a cross-sectional view of the substrate having a first and a second layer as well as a third layer.

FIG. 11 is a cross-sectional view of the substrate with the first and the second layer and contact elements.

FIG. 12 illustrates a first process.

FIG. 13 illustrates a second process.

FIG. 14 illustrates a third process.

FIG. 15 illustrates a fourth process.

FIG. 16 illustrates a fifth process for fabricating a component with an electrical contact.

FIG. 17 illustrates a substrate with a first and a second layer as well as a carrier substrate for connecting.

FIG. 18 illustrates the substrate with the first and the second layer after connecting to the carrier substrate.

FIG. 19 illustrates the substrate including the carrier substrate with filled channels.

FIG. 20 illustrates a substrate including a carrier substrate, the substrate being surrounded by a capping layer.

FIG. 21 illustrates a further embodiment of the component.

FIG. 22 illustrates an arrangement including a substrate, a first and a second layer as well as a carrier substrate.

FIG. 23 illustrates an arrangement including a substrate and a carrier substrate, the channels being filled.

FIG. 24 illustrates a substrate including a carrier substrate and a capping layer.

FIG. 25 illustrates a third layer.

FIG. 26 illustrates a third layer including a first and a second layer.

FIG. 27 illustrates a first, second and third layer with a lower capping layer.

FIG. 28 illustrates the first, second and third layer with filled channels.

FIG. 29 illustrates a further embodiment of the first, second and third layer with contact pads.

FIG. 30 illustrates an arrangement with contact pads and two substrates.

FIG. 31 illustrates the arrangement of FIG. 30 having an intermediate layer.

FIG. 32 illustrates an arrangement with two substrates surrounded by a capping layer.

FIG. 33 illustrates two substrates with contact balls.

FIG. 34 illustrates a layer arrangement connected to the two substrates via contact balls.

FIG. 35 illustrates the layer arrangement including substrates and contact balls, an intermediate layer being provided.

FIG. 36 illustrates an arrangement having two substrates being surrounded by a capping layer.

FIG. 37 illustrates an arrangement for filling the channels in a first process.

FIG. 38 illustrates the arrangement for filling the channels in a second process.

FIG. 39 illustrates the arrangement in a third process.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

An embodiment example of the inventive method may have the advantage that an electrical conductor for contacting an electrical circuit is provided by forming a first and a second layer. By the described method, an electrical conductor structure adapted to contact areas of an electrical circuit may be formed by simple means. The electrical conductor structure allows for safe and reliable electrical contacting of the electrical circuit with low complexity.

For this purpose, a first layer including an electrical conductor having an electrical contact for an electrical circuit is formed, a base layer being provided whereby a first layer with at least one channel is formed on the base layer. The first layer is made of an electrically isolating material. The base layer at least partially covers the channel. A second layer is disposed on the first layer, the second layer having a recess which is at least partially arranged above the channel. The second layer at least partially covers the channel. The channel and the recess are filled with a liquid and after curing of the liquid an electrical conductor is obtained in the channel and in the recess.

In a further embodiment, the base layer is formed as a substrate including an electrical circuit, the electrical circuit having an electrical contact area, the channel being at least partially arranged over the contact area and the electrical conductor being connected to the contact area in an electrically conductive manner. In this way, a secure electrical contacting of the electrical circuit can be achieved.

In another embodiment, the second layer is disposed on an electrically insulating material whereby the second layer includes at least one recess which reaches from an upper side to a lower side of the second layer. This allows for a simple embodiment of a contact area for contacting a further electrical circuit or a further electrical conductor.

In a further embodiment, the first layer is formed of a material which may be patterned by lithographic processes. In this way, the channel in the first layer may be shaped as desired. Furthermore, precise geometries may be obtained by forming the channel.

In a further embodiment, the second layer is formed of a material which may be patterned by lithographic processes. This allows for versatile patterning of the second layer. Thus, improved recesses may be fabricated in order to form an improved contact pad.

In yet another embodiment, the first layer is disposed by a liquid, the liquid being disposed on the base layer and being transformed into an isolating first layer by curing of the liquid, whereby a channel is subsequently formed within the first layer.

In a further embodiment, the first layer is produced from a plastic material, for example a polymer. In a further embodiment, the second layer is produced from plastic material, for example from a polymer. With the use of a polymer for forming the first and/or the second layer, a good patterning with a sufficient electrical isolation of the layers is possible.

In yet another embodiment, the channel is filled up with a liquid metal, for example with liquid solder. This allows for a secure filling of the channel and thus a reliable forming of the electrical conductor.

In a further embodiment, the first and the second layer are laterally extended over the base layer and the recess at the upper side of the second layer is formed laterally with respect to the base layer. This allows for enhanced flexibility when contacting the electrical conductor. For example, the electrical contact with the electrical conductor does not depend on the shape of the base layer. If an electrical circuit is used as base layer, this embodiment offers the possibility of forming the electrical contact of the electrical conductor of the first and second layer on one side of the electrical circuit.

In another embodiment, a third layer having a via hole is disposed on the second layer, the via hole being arranged above the recess of the second layer, the via hole, the recess and the channel being formed as electrical conductor. This allows for further flexibility when forming the electrical conductor.

In a further embodiment, the third layer is configured as a substrate. Furthermore, in a further embodiment the third layer may include a further electrical conductor.

In a further embodiment, an arrangement of the first and the second layer for filling the channel and the recess is immersed in a liquid within a pressure chamber, whereby the pressure within the pressure chamber is increased, whereby the arrangement is extracted from the liquid, whereby the arrangement is cooled and upon cooling the liquid fills the channel and the recess as electrically conductive material and forms an electrical conductor. With the described method, secure filling of the channel can be achieved.

In a further embodiment, the pressure in the pressure chamber is decreased prior to immersing the arrangement in the liquid. Thereby, inclusions in the channel may be avoided or reduced.

In a further embodiment, the arrangement is heated to a temperature above ambient temperature prior to immersion in the liquid.

In a further embodiment, liquid solder is used as liquid. Instead of liquid solder, other liquid materials suitable for forming electrical conductors may also be used for filling the channel.

With an embodiment of the present invention, any desired conductive structures may be formed by using the first layer with a corresponding channel and by using a second layer for at least partially covering the channel. The channel is filled with an electrically conductive material.

In another embodiment, the channel has the same area in a plane of the first side of the first layer and in a plane of the second side of the first layer. This allows for a more precise shaping of the channel.

In order to form the first and/or the second layer, in another embodiment materials may be used which can be patterned by lithographic processes. In another embodiment, a polymer is used for forming the first and/or the second layer. The use of the polymer allows for a simple method for fabricating the first and/or the second layer. Moreover, the channel within the first layer may be shaped as desired by the polymer. Furthermore, the recess within the second layer may be shaped and arranged as desired by the polymer.

In a further embodiment, the base layer is configured as a substrate with an electrical circuit. The electrical circuit is connected to the electrical conductor of the first layer in an electrically conductive manner via corresponding contact pads. Thereby, an arrangement including a substrate with an electrical circuit having an electrical conductor may be obtained, allowing for simple contacting of an electrical circuit.

In another embodiment, the base layer is configured as multi layer having electrical conductors and at least one electrical circuit. In this way, a complex arrangement with a simple contacting of the electrical circuit of the multi layer may be formed.

In a further embodiment, the third layer is configured as multi layer with electrical conductors and at least an electrical circuit.

In yet another embodiment, a substrate is disposed on the second layer which is connected to the electrical conductor in an electrically conductive manner. Moreover, in a further embodiment the substrate may be connected to the second layer via an intermediate layer.

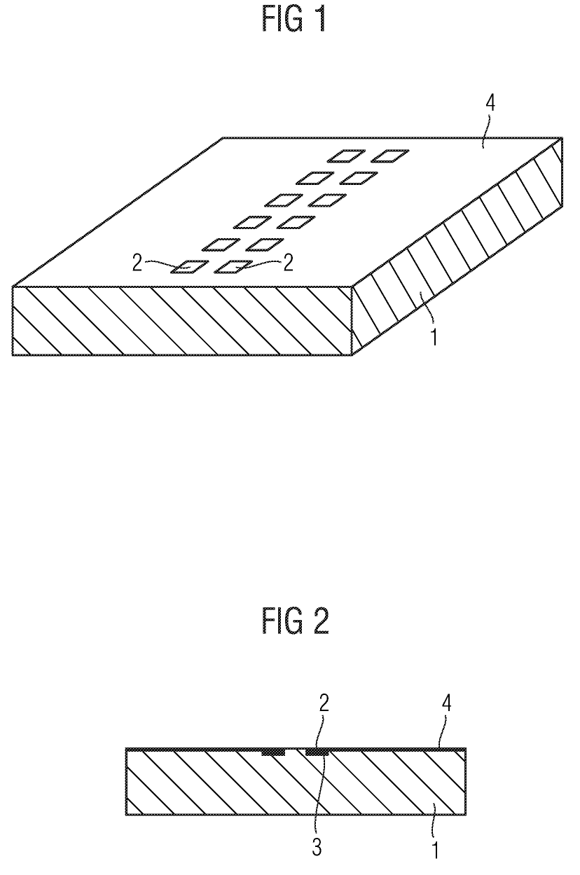

FIG. 1 illustrates a schematic view of a substrate 1 having contact pads 2. The substrate 1 may consist of a wide variety of materials, e.g., a semiconductor material such as silicon. Furthermore, the substrate 1 may also be configured as a sensor element and/or an integrated circuit such as a logic chip or a memory chip. In addition to the contact pads 2, the substrate 1 may include further electrical conductors and/or electrical circuits on or in the substrate 1. Moreover, the substrate 1 may have the shape of a multi layer with electrical conductors and/or electrical sensor elements and/or electrical circuits. In the illustrated example, the substrate 1 is in the shape of a small rectangular plate consisting of silicon, on the surface of which two rows of square contact pads are formed, each row having six contact pads. The second rows of contact pads are arranged in parallel to each other in a central area of the substrate 1. The contact pads 2 may be in the form of an electrically conductive metal layer. Depending on the used embodiment, electrically conductive doped areas may be configured as contact pads 2 on the surface of substrate 1.

FIG. 2 illustrates a cross-sectional view of the substrate 1 and two contact pads 2 arranged side by side. In the illustrated embodiment, the contact pads are arranged in contact recesses 3 disposed in a surface of the substrate 1. An upper side of the contact pads 2 is level with an upper side of the substrate 1. Moreover, the surface of the substrate except for the contact pads 2 may be covered with an isolating layer 4. The isolating layer 4 may consist of silicon oxide.

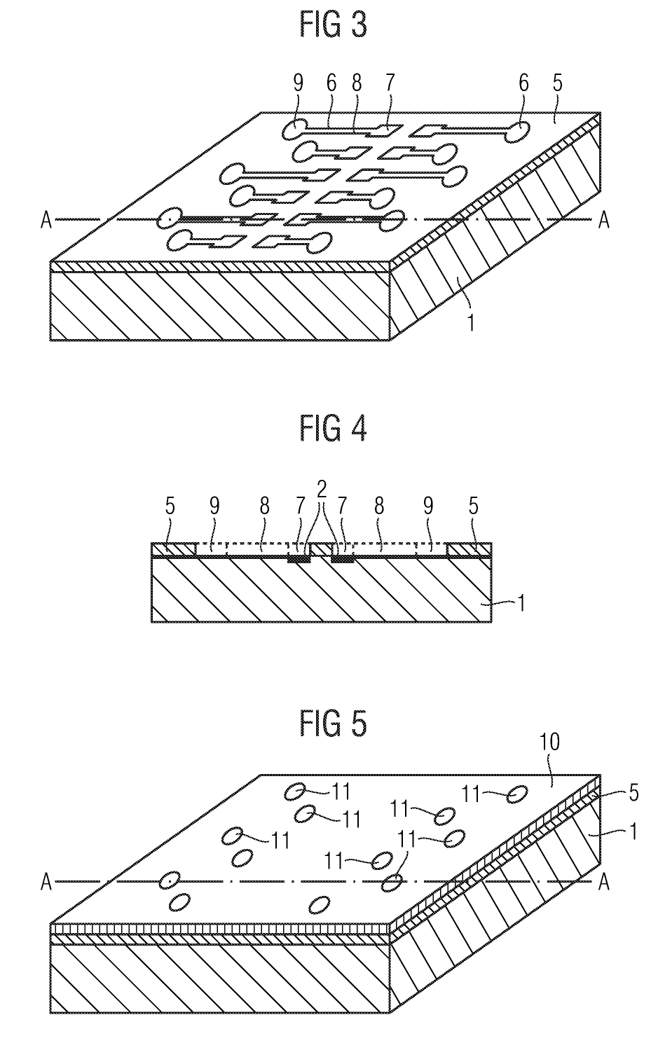

FIG. 3 illustrates a perspective view of the substrate 1 with a first layer 5. The first layer 5 is disposed on the surface of the substrate 1 and includes channels 6. The channels 6 are configured as trenches. In the illustrated embodiment, the channels 6 include a contact section 7, which is connected to a further contact section 9 via a conductor section 8. The contact section 7 is arranged over a contact pad 2. The conductor section 8 is laterally guided away from the contact pad 2 within the layer. The cross-section of the further contact section 9 is in the shape of a circle. The contact section 7 has a rectangular cross-section which is formed according to the cross-sectional shape of the contact pads 2. The conductor sections 8 of the channels 6 are essentially parallel to each other, whereby the conductor sections 8 may have differing lengths.

The first layer 5 consists of an isolating material. For the material, e.g., materials may be used which can be patterned in photolithographic processes. Furthermore, the first layer 5 may consist of a film into which the channels 6 have been introduced. The film may consist of a plastic material. The film can be patterned by local removal such as etching, stamping or laser processing, in order to introduce e.g., channels 6. The channels 6 may be introduced into the first layer 5 by stamping methods, etching methods using covering masks, or by cutting methods such as laser cutting. Depending on the selected embodiment, the first layer 5 may be produced on a carrier material independently from the substrate 1 and then connected to the substrate 1. Thereby, the first layer 5 may for example be applied and glued to the substrate 1. The first layer may moreover be fabricated from a plastic material, e.g., a polymer.

Furthermore, the first layer 5 may be fabricated from photo resist whereby the liquid photo resist is disposed on the surface of the substrate 1 and whereby by a covering mask only those areas of the photo resist are illuminated and cured in which the first layer 5 is to be formed. Thereby, the sections of the channels 6 are not cured and washed off the substrate 1 in a subsequent washing process. Moreover, it may be possible to cover the entire substrate 1 surface with the photo resist layer, to cure the entire surface and subsequently form the channels 6 in the first layer 5 by etching processes. Thereby, dry etching or wet etching may be used.

FIG. 4 illustrates a cross-section of a substrate 1 along an intersection axis A-A of FIG. 3. In this embodiment it can be clearly seen that the contact sections 7 of the channels 6 are arranged above the contact pads 2. Moreover, the channels 6 have the same cross-sectional area at an upper side of the first layer 5 and at a lower side of the first layer 5.

Thereby, the cross-section is guided through the circular further contact sections 9, along the conductor sections 8 and through the contact sections 7. In the first layer 5, the channels 6 are configured as recesses which are suitable for forming an electrical conductor by filling the channels 6. The level of the first layer 5 may be selected differently, depending on the selected embodiment. The level of the first layer 5 may e.g., be in the range of 5 to 20 μm.

FIG. 5 illustrates a further process stage in which a second layer 10 has been disposed on the first layer 5 including the channels 6. The second layer 10 e.g., consists of an electrically isolating material and may e.g., be produced in the shape of a film which is provided with the recesses 11 and disposed on the first layer 5. In the illustrated embodiment, the recesses 11 are formed as circular recesses which are arranged above further contact sections 9 of the channels 6. The second layer 10 can be fabricated from the same materials as the first layer 5. For example, the second layer 10 may be fabricated from a plastic material, in particular a polymer, from a material which can be patterned in photolithographic processes, or from a film consisting of electrically isolating material. Moreover, the recesses 11 may be etched, stamped or cut into the second layer 10. The level of the second layer 10 may also be selected differently depending on the embodiment as in the case of the first layer 5. The level of the second layer 10 may e.g., be in a range between 5 and 20 μm. In order to fasten the second layer 10 to the first layer 5, gluing processes or a gluing layer may be employed.

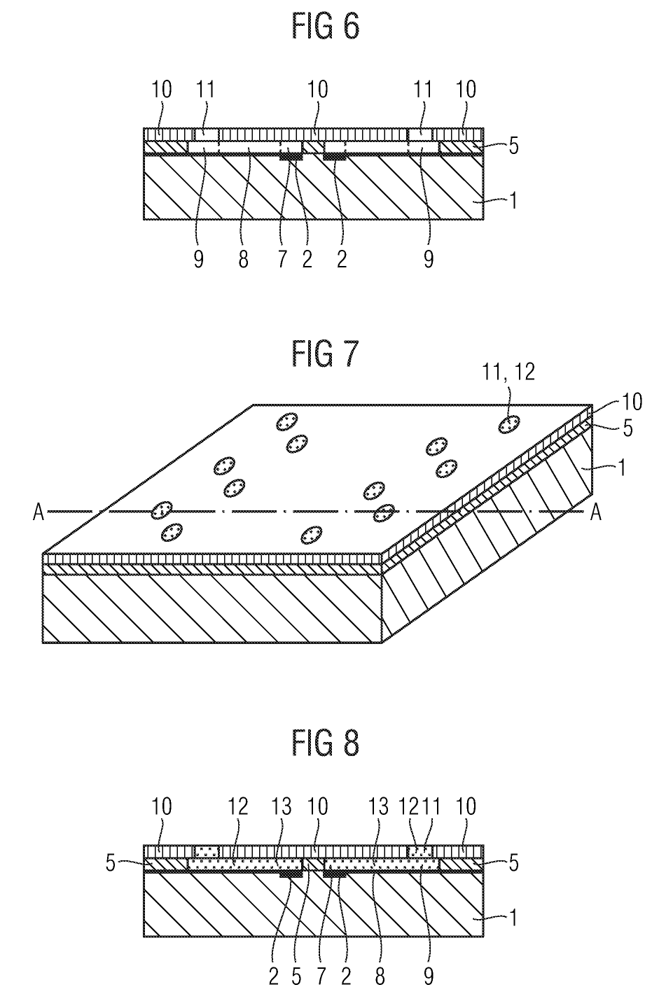

FIG. 6 illustrates a cross-section of the substrate 1 having the first and the second layer 5, 10 of FIG. 5 along the intersecting line A-A. Thereby, it can clearly be seen that the channels 6 of the first layer 5 are covered by the second layer 10, the recesses 11 of the second layer 10 being arranged above the further contact sections 9.

In a further process the channels 6 including the recesses 11 are filled with an electrically conductive material. Thereby, e.g., liquid metal such as liquid solder may be used in order to fill the channels 6 and the recesses 11.

FIG. 7 illustrates the substrate 1 with the first and the second layer 5, 10, whereby the channels 6 including the recesses 11 are filled with an electrically conductive material 12.

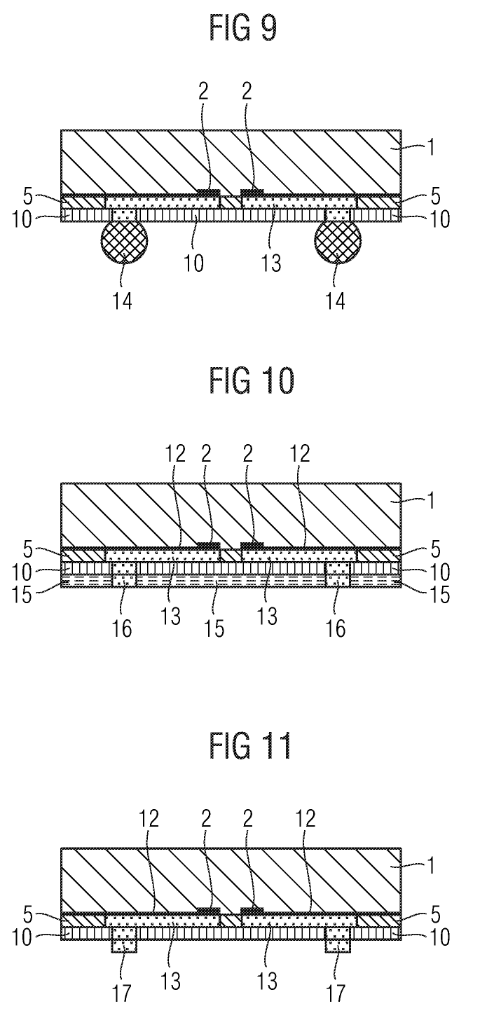

FIG. 8 illustrates a cross-section of the intersecting line A-A of FIG. 7. From the cross-section of FIG. 9, it can be clearly seen that the electrical conductor 13 is guided to a contact pad 2 starting from the surface of the second layer 10 via the recess 11, the further contact section 9, the conductor section 8 and the contact section 7 of the channels 6.

FIG. 9 illustrates a cross-section along the intersecting line A-A of FIG. 8, whereby contact elements 14 have been disposed on the recesses 11 in the shape of contact balls, e.g., consisting of tin-solder.

FIG. 10 illustrates a further process in which a sacrificial layer 15 with continuous apertures 16 has been disposed on the second layer 10, the apertures 16 being formed above the recesses 10. Upon filling the channels with the recesses 11 and the apertures 16 with the electrically conductive material 12, the sacrificial layer 15 is removed in a subsequent process stage. Thus, an arrangement with an electrical conductor 13 having contact end pieces 17 is obtained, the contact end pieces 17 protruding over the second layer 10, as illustrated in FIG. 11.

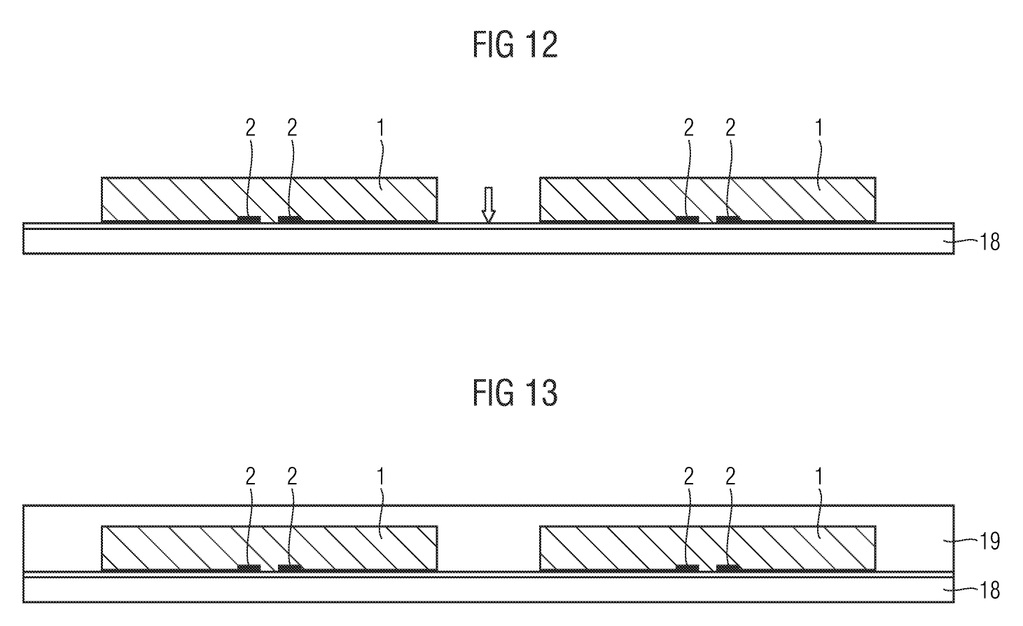

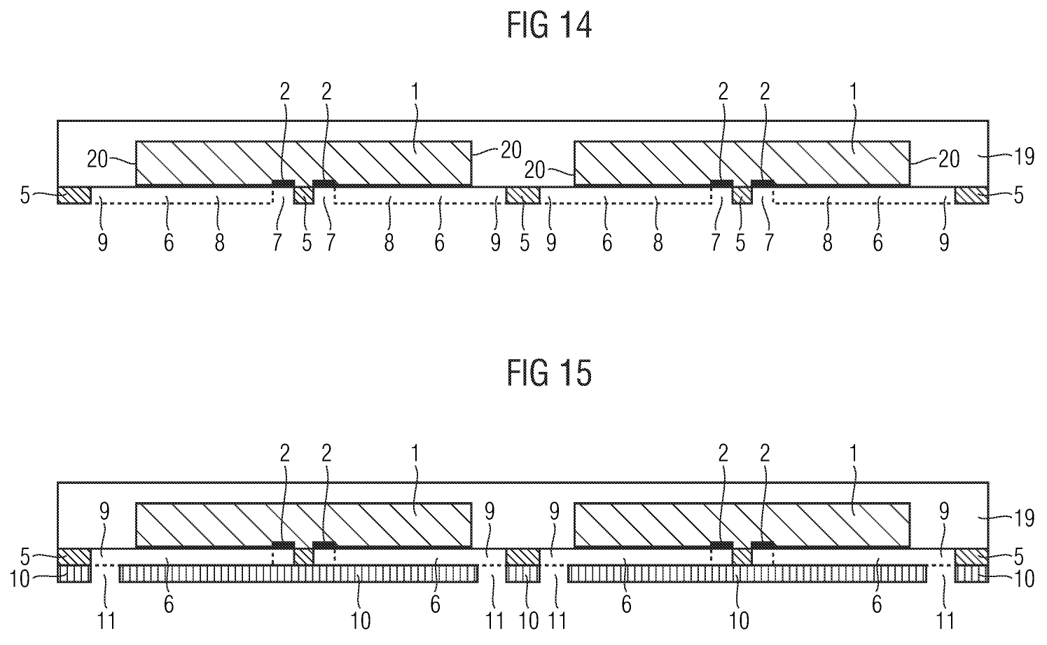

FIGS. 12 to 16 illustrate a further method for producing an electrical conductor 13 for contacting a substrate 1, whereby the further contact pads of the electrical conductor 13 are arranged laterally with respect to the substrate 1. The substrate 1 may include electrical conductors and/or sensor elements and/or electrical circuits. For example, the substrate 1 may be configured as an electrical or electronic circuit such as a logic circuit or a memory device. For the purposes of a clearer illustration, only the substrate 1 and the contact pads 2 are illustrated explicitly. FIG. 12 illustrates a process stage in which two substrates 1 are arranged side by side on a carrier plate 18. Thereby, the substrate 1 lies on an upper side of the carrier plate 18 with the contact pads 2.

In a further process stage, the two substrates 1 are surrounded by a capping layer 19. The capping layer 19 is disposed on the uncovered surface of the substrate 1 and on the upper side of the carrier plate 18. The capping layer 19 may consist of an isolating material, e.g., a plastic material. This process stage is illustrated in FIG. 13.

In a further process stage, the carrier plate 18 is removed and a first layer 5 having at least one channel 6 is disposed on the uncovered side of the substrate 2 and on the uncovered side of the capping layer 19. Thereby, the channels 6 are configured with a contact section 7 above the contact pads 2, as described with reference to FIGS. 3 and 4. The conductor sections 8 protrude laterally over the lateral area 20 of the substrate 1. On the side of the substrates 1, the further contact sections 9 of the channels 6 are formed. Thus, the uncovered surfaces of the contact pads 2 are adjacent to the contact sections 7 of the channels 6. This process stage is illustrated in FIG. 13. Depending on the selected embodiment, any desired shapes of channels 6 may be formed, e.g., the further contact sections 9 of the channels 6 may be formed in the area of the substrates 1, i.e. below the substrates 1 in the selected illustration.

In a further process stage, a second layer 10 is disposed on the first layer 5, the second layer 10 covering the channels 6 except for the recesses 11. The second layer 10 is formed as described with reference to FIGS. 5 and 6. The recesses 11 of the second layer are formed in the area of the further contact sections 9. In the selected embodiment, the recesses 11 are arranged in a laterally shifted manner opposite to the substrates 1. In this way, the channels 6 are formed, which are guided from an uncovered surface of the contact pads 2 to an uncovered side of the second layer 10, i.e. the recesses 11. This process stage is illustrated in FIG. 15.

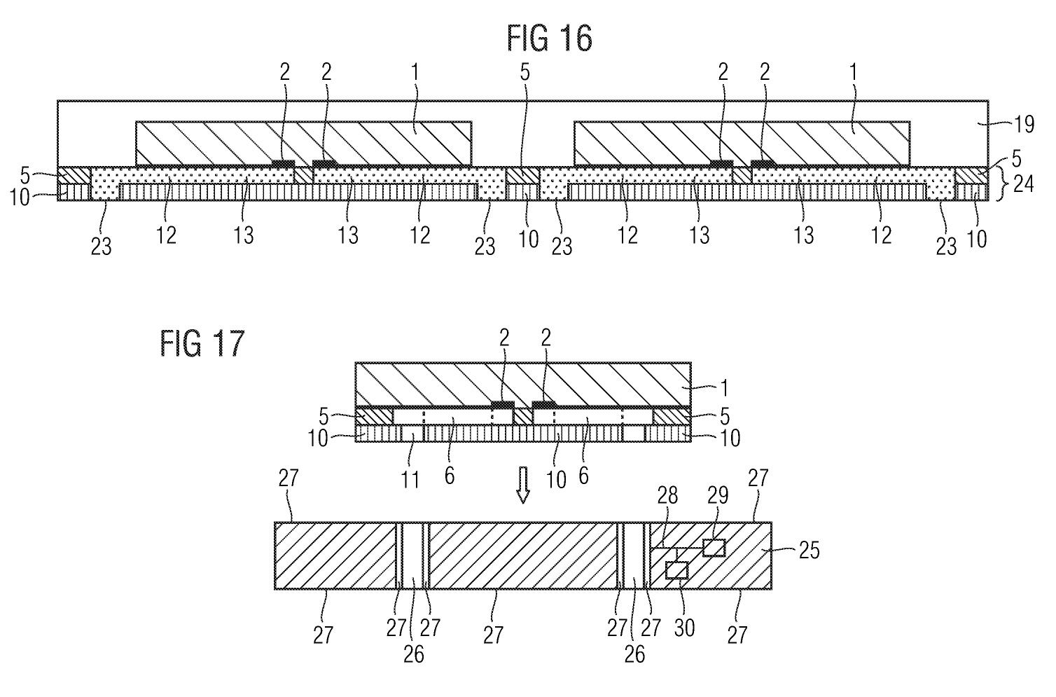

In a following process, the channels 6 are filled with an electrically conductive material 12. This process stage is illustrated in FIG. 16. As already stated with reference to FIGS. 7 and 8, liquid metal, e.g., liquid solder may be used as electrically conductive material. As a result, a component 21 is obtained having a substrate 1 with contact pads 2 which are in an electrically conductive connection to a further contact pad 23 via electrical conductors 23. The further contact pads 23 are formed on the uncovered side of the second layer 10.

Due to the described method, various shapes of conductor structures may be produced for electrically contacting the contact pads 2 of the substrate 1. Particularly, the levels of the electrical conductors 13 may be determined precisely by the level of the first layer 5. Furthermore, the widths of the electrical conductors 13 may be determined by a corresponding patterning or dimensioning of the widths of the channels 6. Furthermore, the geometry and the position of the further contact pads 23 is possible by corresponding patterning of the channels 6 and of the second layer 10 including the recesses 11. Thus, a simple and flexible method for fabricating a conductor layer 24 is obtained providing a first and a second layer 5, 10 including electrical conductors 13, which are formed in the channels 6 of the first layer 5 and in the recesses 11 of the second layer 10.

FIG. 17 illustrates a substrate 1 having contact pads 2, a first and a second layer 5, 10, whereby in the first layer 5 channels 6 and in the second layer 10 recesses 11 are formed according to the process stage of FIG. 6. Moreover, a further carrier plate 25 is illustrated with further recesses 26. The further recesses 26 are in the shape of holes arranged according to the recess 11 arrangement of the second layer 10. The further recesses 26 may have a cross-section which corresponds at least to the size of the recesses' 11 cross-section. A layer consisting of a semiconductor material, a ceramic material, a metal, a polymer or a printed circuit board may for example be provided as a further carrier plate 25. In the configuration of the further carrier plate 25 by an electrically conductive material such as a semiconductor or a metal, the sidewalls of the further recesses 26 are provided with a second electrical isolating layer 27. Furthermore, the surfaces of the further carrier plate 25 may be covered by a second electrical isolating layer 27. The further carrier plate 25 may include further electrical circuits, such as logic circuits, a memory circuit, a sensor circuit or further electrical conductors. Moreover, the further carrier plate 25 may be a multi layer and include in particular a resistive element, a capacitive element or an inductive element. In the illustrated embodiment, a further electrical conductor is provided in the further carrier plate 25, to which a further electrical circuit 29 as well as an electrical component 30 are connected.

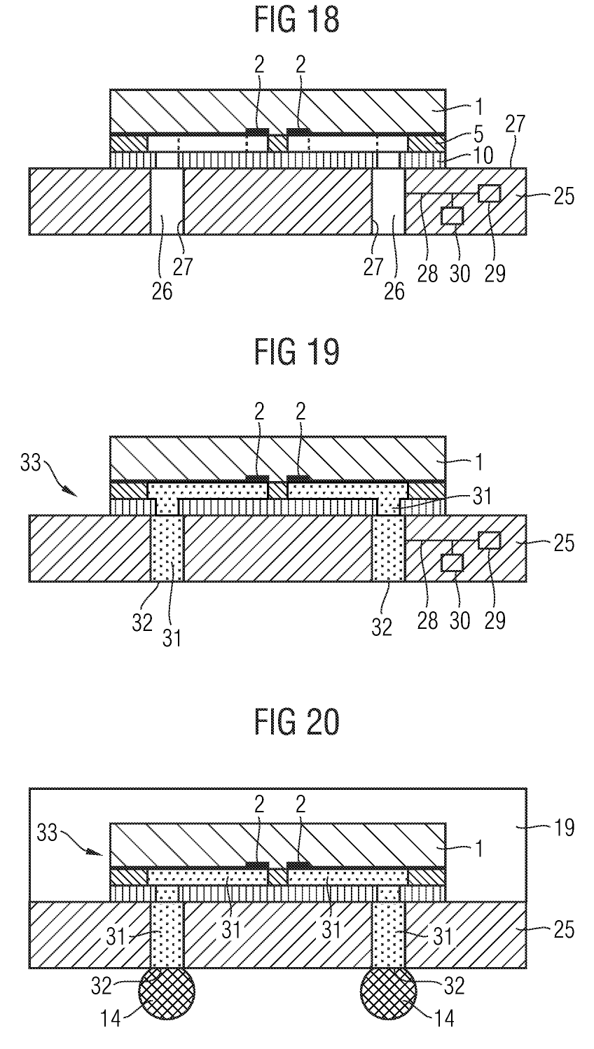

In order to form a third component, the substrate 1 is fastened to the further carrier plate 25 by the first and the second layer 5, 10, whereby the second layer 10 is applied on an upper side of the further carrier plate 25. Thereby, the recesses 11 and the further recesses 26 are arranged adjacent to each other in an at least partially overlapping manner. This process stage is illustrated in FIG. 18. In a further process, the further recesses 26, the recesses 11 and the channels 6 are filled with an electrically conductive material, in particular a liquid metal, and third electrical conductors 31 are obtained which connect the contact pads 2 of the substrate 1 to third contact pads 32 in an electrically conductive manner, whereby the third contact pads 32 are arranged on an uncovered side face of the further carrier plate 25. This process stage is illustrated in FIG. 19. Due to the forming of a further electrical connector 28 in the further carrier plate 25, the electrical circuit 29 and the electrical component 30 are also connected to the third electrical connector 31 in an electrically conductive manner. This results in a third component 33.

Depending on the further use of the third component 33, the third component 33 may be surrounded by a capping layer 19, whereby the capping layer 19 is disposed on the uncovered surfaces of the substrate 1, on the first layer 5, on the second layer 10 and on one side of the further carrier plate 25, on which the substrate 1 with the first and the second layer 5, 10 is arranged. Moreover, the third contact pads 32 may be provided with a contact element 14, e.g., with contact balls 32. This process stage is illustrated in FIG. 20. The capping layer 19 may consist of a plastic material, as already described above.

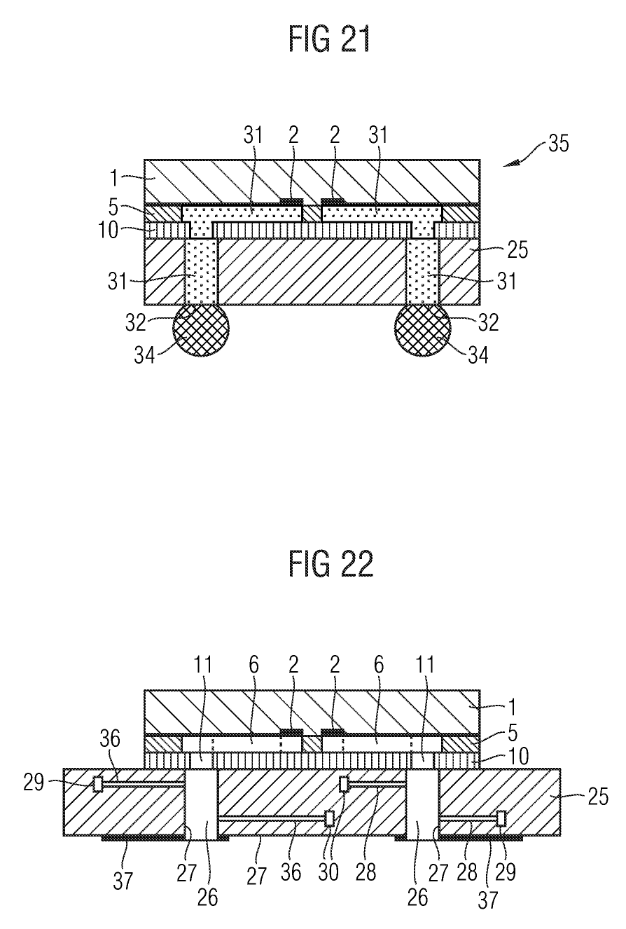

In a further embodiment, the footprint of the further carrier plate 25 is configured according to the footprint of the substrate 1. Furthermore, the third contact pads 32 may also be provided with contact elements 14, e.g., contact balls. In this manner, a fourth component 35 is obtained which has a small design. The fourth component 35 is illustrated in FIG. 21.

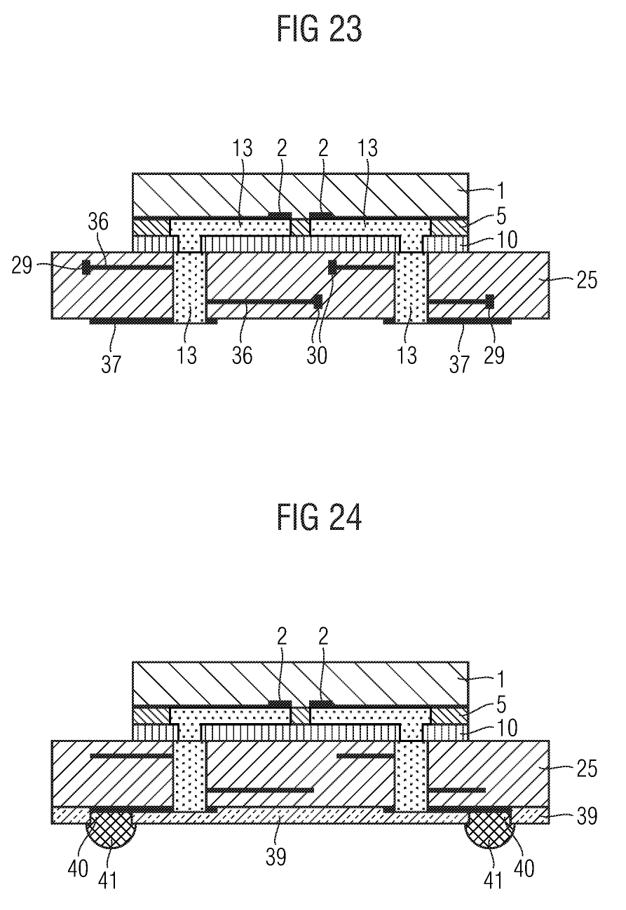

FIG. 22 illustrates an arrangement having a substrate 1 having two contact pads 2, a first layer 5 with channels 6, a second layer 10 with recesses 11 and a further carrier plate 25 with further recesses 26. The first layer 5 is disposed on the substrate 1, the contact pads 2 being at least partly adjacent to the channels 6. The second layer 10 is disposed on the first layer 5. The carrier plate 25 is located on the second layer 10. The further recesses 26 form a continuous channel together with the recesses 11 and the channel 6. Moreover, the further carrier plate 25 is configured as a multi layer or a multi layer substrate, respectively. Thereby, the further carrier plate 25 may have further channels 36 which are connected to further recesses 26. The further channels 36 are guided towards contacts of a further electrical circuit 29 and an electrical component 30. Moreover, the further channels 36 are provided with an electrical isolating layer 27. In addition, the further carrier plate 25 may include further electrical conductors 28 which are connected to a further electrical circuit 29 and/or to an electrical component 30. Moreover, the further carrier plate 25 may include fourth electrical conductors 37 on its uncovered side, the fourth electrical conductor 37 being adjacent to further recesses 26. This process state is illustrated in FIG. 22. In a further process, the channels 6, the recesses 11, the further recesses 26 and, if present, the further channels 36 are filled with an electrically conductive material such as a liquid metal. The liquid metal is subsequently cooled and an electrical conductor 13 is obtained. The electrical conductor 13 connects the contact pads 2 to the further electrical conductors 28, the fourth electrical conductor 37 and moreover to the further electrical circuit 29 and the electrical component 30 in an electrically conductive manner, the contact pads of the electrical circuit 29 and of the electrical component 30 being adjacent to the further channels 36. This process stage is illustrated in FIG. 23.

Depending on the further use, another isolation layer 39 may be disposed on an uncovered side of the further carrier plate 25, on which the fourth conductors 37 have been arranged. The further isolation layer 39 has contact apertures 40 in which electrically conductive further contact elements 41, e.g., in the shape of partial balls are provided. The contact apertures 40 are formed in the area of the fourth conductors 37 so that an electrically conductive connection between the further contact elements 41 and the fourth conductors 37 is established. This process stage is illustrated in FIG. 24.

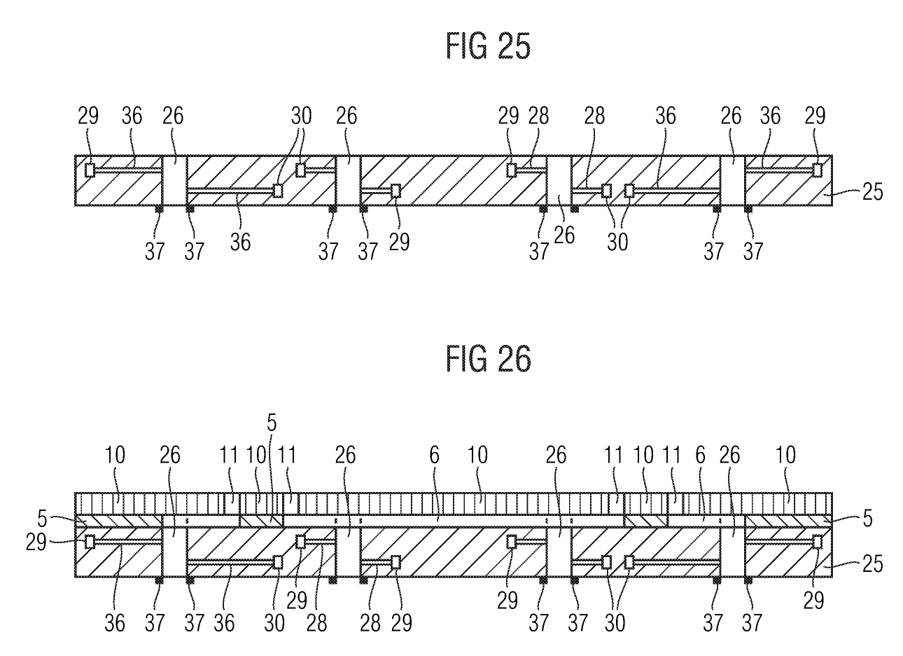

FIGS. 25 to 32 illustrate a further process for producing a fourth component 42. In the first process illustrated in FIG. 25, a further carrier plate 25 is provided having further channels 36, to which contact pads of a further electrical circuit 29 and/or of an electrical component 30 abut. The further channels 36 open into further recesses 26. In addition, further electrical conductors 28 are provided in the further carrier plate 25, which may be connected to a further electrical circuit 29 and/or to an electrical component 30. Moreover, the further carrier plate 25 may include fourth conductors 37 on one side, which circularly surround the further recesses 26. The further recesses 26 are shaped as via holes. The further carrier plate 25 may be a multi layer.

In an additional process, a first layer 5 with channels 6 is disposed on the carrier plate 25. Moreover, a second layer 10 with recesses 11 is disposed on the first layer 5. The channels 6 are configured in such a way that the channels 6 are connected to the further recesses 26. Furthermore, the recesses 11 are also connected to the channels 6. This results in the provision of a layer arrangement having a channel structure, the further recesses 26 being connected to the further channels 36, to the channels 6 and to the recesses 11. Depending on the chosen embodiment, the channel structure may be configured such that a recess 11 is connected to a further recess 26. This process stage is illustrated in FIG. 26.

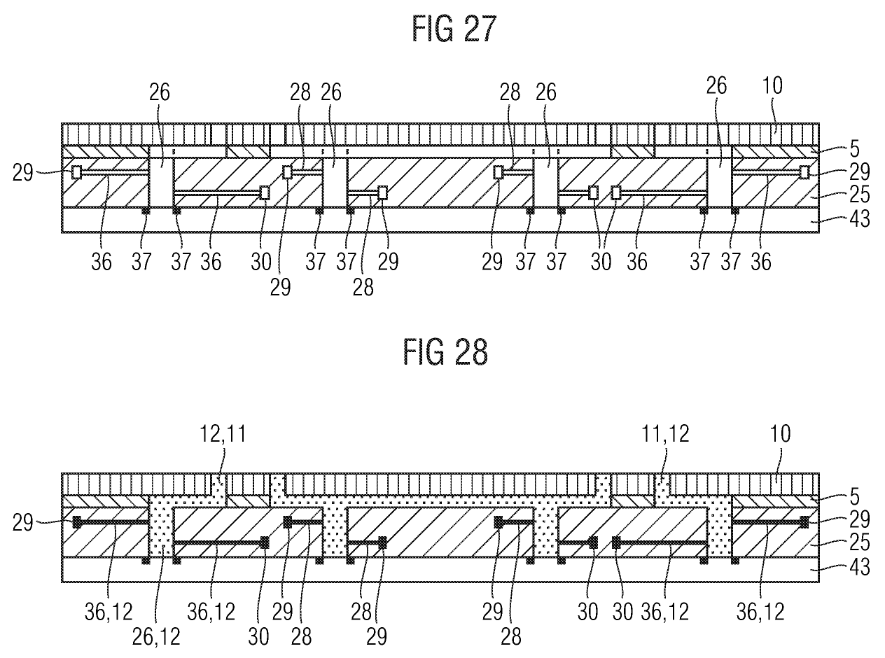

In a further process, a covering layer 43 is disposed on an uncovered side of the further carrier plate 25, from which the further recesses 26 start and in which depending on the chosen embodiment fourth conductors 37 are formed. The covering layer 43 serves for sealing off the further recesses 26 on one side. This process stage is illustrated in FIG. 27.

In a further process stage, the channel structure of the layer arrangement of FIG. 27 is filled up with an electrically conductive material, such as a liquid metal. The liquid metal is cooled after filling. Thereby, a ramified electrically conductive conductor structure is obtained as conductor 13. The further channels 36 and the further electrical conductors 28 are connected to the electrical conductor structure, as well. In addition, the recesses 11, the channels 6 and the further recesses 26 are filled with the electrically conductive material. This process stage is illustrated in FIG. 28. The fourth conductors 37 are also connected to the conductor structure in an electrically conductive manner.

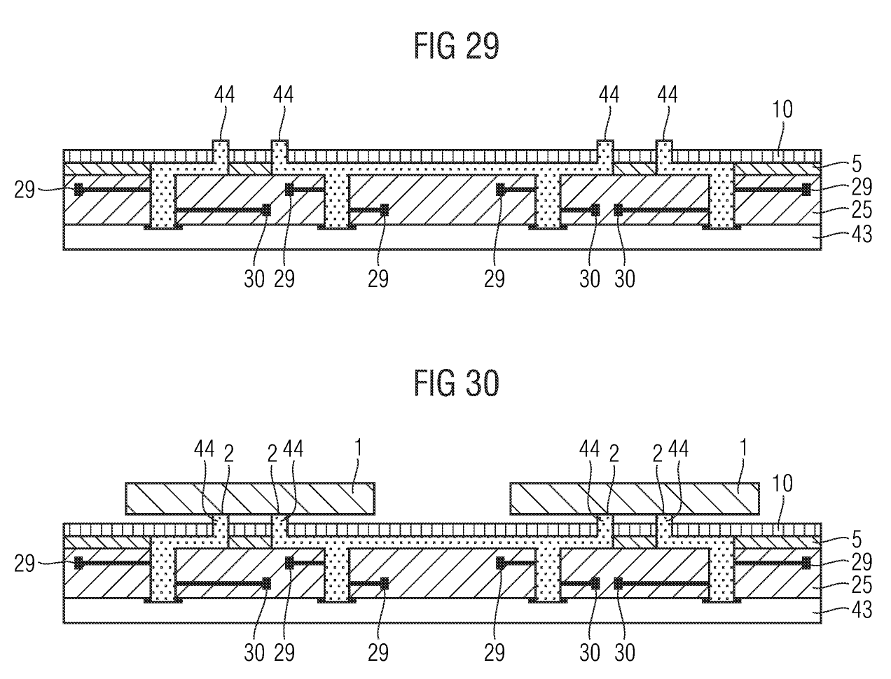

In a further process, an upper side of the second layer 10, which is uncovered, is removed, thus obtaining uncovered contact sections 44. In order to remove the second layer 10, wet etch techniques and/or dry etching may be employed. This process stage is illustrated in FIG. 29.

Subsequently, substrates 1 having contact pads 2 are applied to the contact sections 44. The contact pads 2 are connected to the contact sections 44 in an electrically conductive manner. Using a reflow process, for example, a mechanically rigid and electrically conductive connection between the contact pads 2 of the substrates 1 and the contact sections 44 may be produced. This process stage is illustrated in FIG. 30.

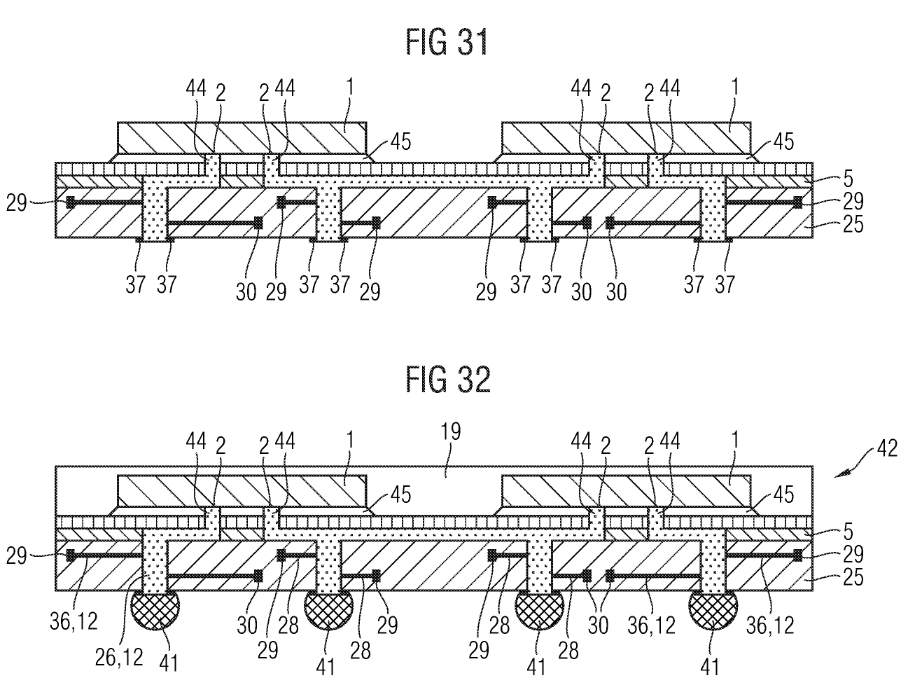

Subsequently, a filler layer 45, which is electrically isolating, is disposed between the substrate 1 and the second layer 10, at least the contact sections 44 being surrounded by the filler layer 45. The filler layer 45 on the one hand provides a mechanical connection and fastening of the substrate 1 on the second layer 10 and on the other hand an electrically isolating envelope for the contact sections 44. In addition, the covering layer 43 may be removed and the filled-up further recesses 26 including the fourth conductors 37 may be uncovered. This process stage is indicated in FIG. 31. Thereafter, a capping layer 19 may be disposed on the substrate 1 and the corresponding lateral surfaces of the second layer 10. Moreover, a further contact element 41, e.g., a contact ball, may be applied on the uncovered further recesses 26 and/or on the fourth conductors 37. This process stage is illustrated in FIG. 32. The circular arrangement of the further electrical conductor 37 offers the possibility of filling the created circular space with electrically conductive material, as well. This results in raised conductor sections which may easily be contacted by the further contact elements.

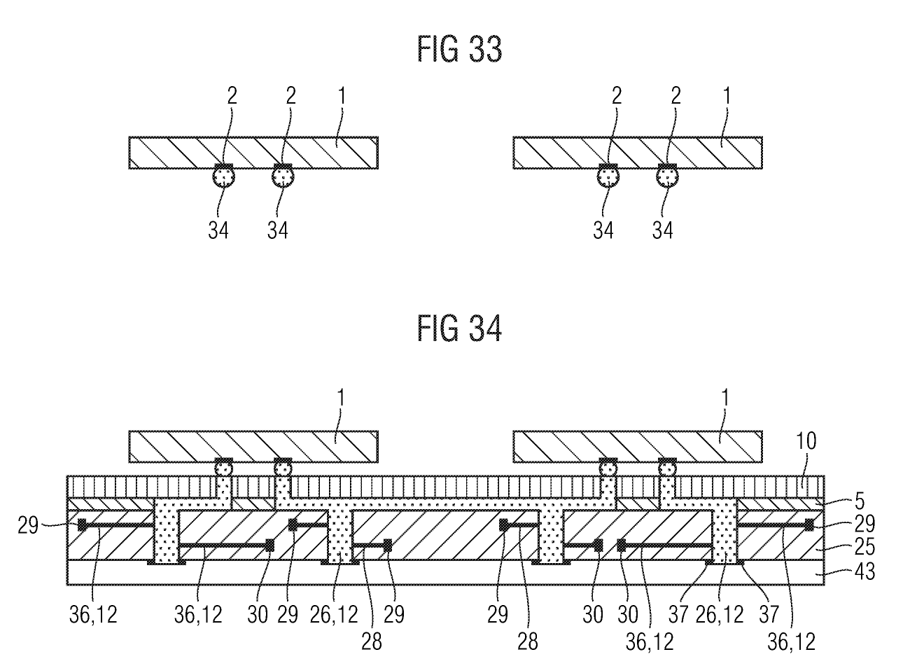

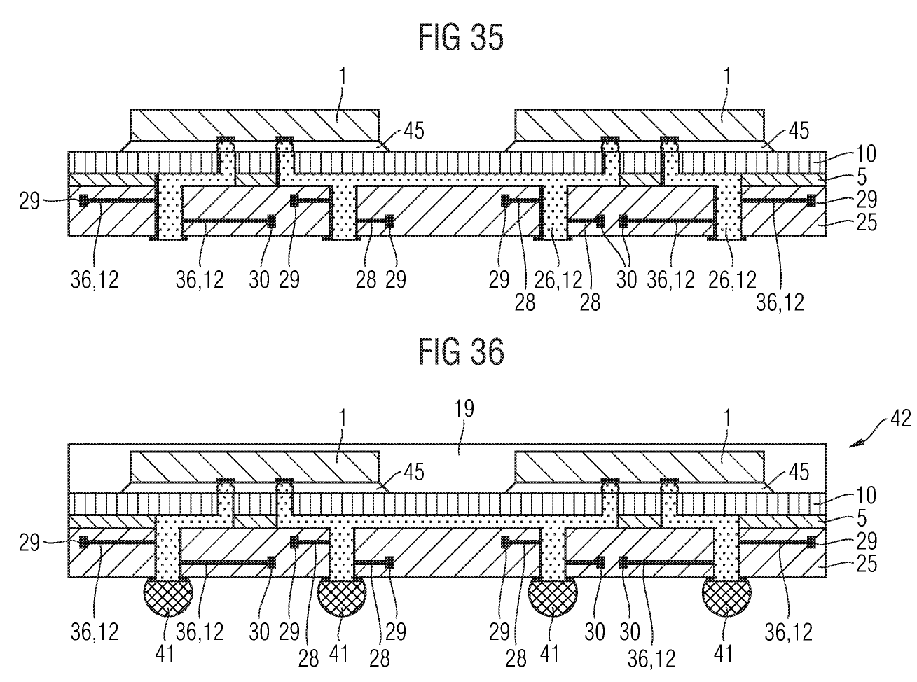

FIGS. 33 to 36 illustrate a further method for fabricating a component. In FIG. 33, substrates 1 having contact pads 2 are provided, whereby contact elements 41, e.g., contact balls, are disposed on the contact pads 2. In the present process, the substrates 1 including the contact elements 41 are disposed on a layer arrangement as illustrated in FIG. 28. Thereby, the contact elements 41 are disposed on the uncovered surfaces of the recesses 11 and connected to the electrically conductive filling 12 of the recesses 11 in an electrically conductive as well as mechanical manner. This process stage is illustrated in FIG. 34. Subsequently, a filler layer 45 is disposed between the substrate 1 and the second layer 10. The filler layer 45 consists of an electrically isolating material and surrounds at least the contact elements. Furthermore, the covering layer 43 is removed. This process stage is illustrated in FIG. 35. Thereafter, the substrates 1 are covered with a capping layer 19, the capping layer 19 being also applied to the side of the second layer 10 associated with the substrates 1. Additionally, contact balls 34 are disposed on the third contact pads 32. This process stage is illustrated in FIG. 36.

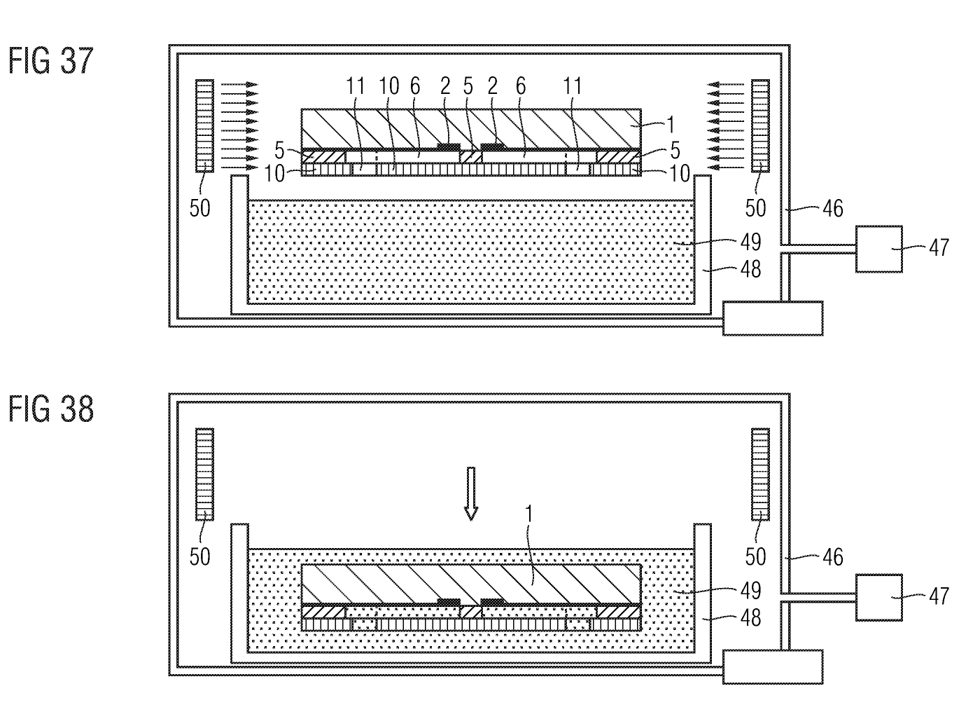

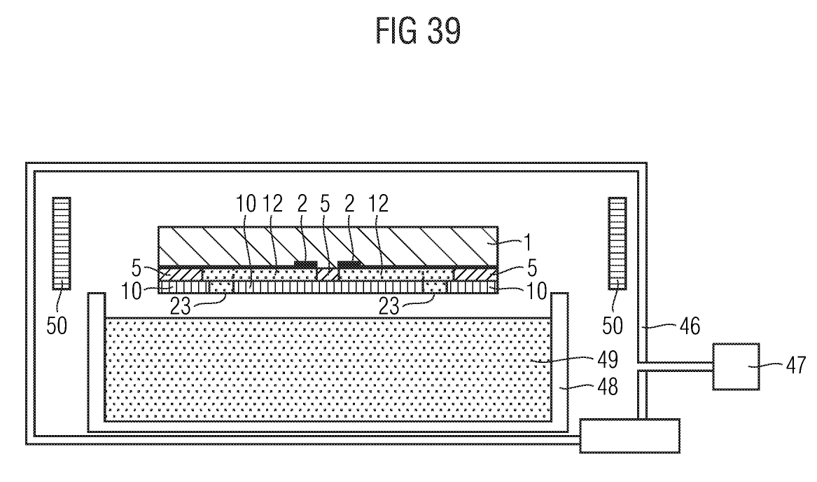

FIG. 37 illustrates an arrangement used for filling a channel structure. Thereby, a pressure chamber 46 connected to a vacuum pump 47 is provided. Within the pressure chamber 46, a vat 48 with an electrically conductive liquid 49, e.g., liquid solder, is provided. In addition, heating elements 50 may be provided on opposite sides of the vat 48. Moreover, a layer arrangement having a channel structure is provided. In the illustrated example, the layer arrangement includes a substrate 1 with contact pads 2 adjacent to channels 6 of a first layer 5. Thereby, the first layer 5 is disposed on the side of the substrate 1 on which the contact pads 2 are formed. Moreover, a second layer 10 is disposed on the first layer 5, the second layer 10 having recesses 11 which are at least partially adjacent to the channels 6 of the first layer 5. Depending on the selected embodiment, any desired negative pressure may be introduced to the pressure chamber 46 by the vacuum pump 47. Additionally, the layer arrangement may be heated to a predetermined temperature, e.g., the temperature of the liquid 49, by the heating elements 50. Subsequently, the layer arrangement as illustrated in FIG. 36 is completely immersed in the liquid 49. Thereby, the channels 6 and the recesses 11 are filled with the liquid. Moreover, the pressure in the pressure chamber 46 may be increased by the vacuum pump 47. A pressure pump may be provided instead of the vacuum pump 47. By increasing the pressure after immersing the layer arrangement in the liquid 49, the liquid 49 is pressed into the channel structure of the layer arrangement, thus largely filling the channel structure. Subsequently, the layer arrangement is extracted from the vat 48 and the filled layer arrangement is cooled. Upon cooling of the layer arrangement or during cooling of the layer arrangement, the pressure in the pressure chamber 46 is reset to ambient pressure. During cooling, the liquid 49 solidifies to result in an electrically conductive material 12 filling the channel structure of the layer arrangement. This process stage is illustrated in FIG. 39. In this way, a layer arrangement with an electrical conductor 13 is obtained, connecting the contact pads 2 of the substrate 1 to further contact pads 23 on a lateral surface of the second layer 10 in an electrically conductive manner.

The method described with references to FIGS. 37 to 39 may be used for the various embodiments of the layer arrangement described with reference to the foregoing Figures in order to fill channels of the layer arrangement with an electrically conductive material.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for fabricating a circuit arrangement comprising:
providing a base layer and first layer with at least one channel being disposed on the base layer, the first layer being fabricated from an electrically isolating material, the base layer at least partially covering the channel;
a second layer being disposed on the first layer; the second layer having a recess; the second layer at least partially covering the channel; the recess being at least partially arranged above the channel;
filling the channel and the recess with a liquid; and
curing the liquid, an electrical conductor being formed in the channel and in the recess, the electrical conductor having an electrical contact for a circuit.

2. The method according to claim 1, comprising:
configuring the base layer as a substrate with an electrical circuit, the electrical circuit comprising an electrical contact area, the channel being at least partially arranged over the contact area and the electrical conductor being connected to the contact area in an electrically conductive manner.

3. The method according to claim 1, comprising:
disposing the second layer consisting of an electrically isolating material, the second layer comprising at least one recess reaching from an upper side to a lower side of the second layer.

4. The method according to claim 1, comprising:
forming the channel in the first layer using a lithographic patterning processes.

5. The method according to claim 1, comprising:
forming the recess in the second layer using a lithographic patterning processes.

6. The method according to claim 1, comprising:
disposing liquid photo resist on the base layer, the photo resist then being cured to an isolating first layer comprising a channel.

7. The method according to claim 1, comprising:
fabricating the second layer from a film which may be patterned by photolithographic processes, the film being cured resulting in an isolating second layer comprising a recess and the second layer being disposed on the first layer.

8. The method according to claim 1, comprising:
fabricating the second layer from a film and carrying out the patterning by local removal.

9. The method according to claim 1, comprising:
fabricating the first layer from a plastic material including a polymer.

10. The method according to claim 1, comprising:
fabricating the second layer from a polymer.

11. The method according to claim 1, comprising:
filling the channel with liquid metal.

12. The method according to claim 1, comprising:
filling the recess with liquid metal.

13. The method according to claim 1, comprising
the first and the second layer extending laterally over the base layer; and
forming the recess at the upper side of the second layer on one side of the base layer.

14. The method according to claim 1, wherein a third layer comprising a continuous further recess being disposed on the third layer, further recesses being arranged over the recess, the further recess, the recess and the channel being configured as an electrical conductor.

15. The method according to claim 13, comprising using a substrate as third layer.

16. The method according to claim 13, wherein the third layer comprising a further electrical conductor which is in an electrically conductive connection to the electrical connector.

17. The method according to claim 13, wherein the third layer comprising a further electrical conductor adjacent to a further recess and being in an electrically conductive connection to the electrical conductor.

18. The method according to claim 1, comprising:
immersing the layer arrangement consisting of a first and a second layer in a liquid in a pressure chamber in order to fill the channel and the recess;
subsequently increasing the pressure in the pressure chamber;
extracting the arrangement from the liquid;
cooling the arrangement;
solidifying the liquid to result in an electrically conductive material; and
increasing the pressure in the pressure chamber.

19. The method according to claim 18, comprising decreasing the pressure in the pressure chamber prior to immersing the layer arrangement.

20. The method according to claim 18, comprising heating the layer arrangement to a temperature above ambient temperature prior to immersion in the liquid.

21. The method according to claim 1, comprising using liquid solder as a liquid.

22. A circuit arrangement comprising:
a contact layer having a first layer with a channel which is filled with electrically conductive material;
the first layer being disposed on the base layer;
the channel configured as a recess in the first layer;
the recess extending from the upper side of the first layer to the lower side of the first layer; the base layer at least partially covering the channel on a first side of the first layer; and
a second layer being disposed on a second side of the first layer and partially covering the channel, the second layer comprising a recess which is at least partially arranged above the channel and filled with an electrically conductive material, forming an electrical conductor.

23. The arrangement according to claim 22, the channel comprising an equally large area in a plane of the first side of the first layer and in a plane of the second side of the first layer.

24. The arrangement according to claim 22, comprising the first layer being fabricated from a photo resist.

25. The arrangement according to claim 22, comprising the first layer being fabricated from a plastic material, such as a polymer.

26. The arrangement according to claim 22, comprising the base layer being configured as a substrate with an electrical circuit, the substrate comprising an electrical contact area adjacent to the channel of the first layer and being in electrically conductive connection to the electrical connector.

27. The arrangement according to claim 22, comprising the channel protruding laterally over the substrate and the recess of the second layer being arranged on one side of the substrate.

28. The arrangement according to claim 22, comprising a third layer being arranged on the second layer, the third layer comprising a further continuous recess which at least partially covers the recess of the second layer, and the further recess being filled with an electrically conductive material and forming a part of the electrical connector.

29. The arrangement according to claim 22, comprising the base layer being covered with an isolating layer.

30. The arrangement according to claim 28, the third layer comprising electrical conductors.

31. The arrangement according to claim 28, the third layer comprising an electrical circuit connected to the electrical conductor.

32. The arrangement according to claim 22, comprising the base layer being a multi layer with electrical conductors and at least one electrical circuit.

33. The arrangement according to claim 28, comprising the third layer being a multi layer with electrical conductors and at least one electrical circuit.

34. The arrangement according to claim 22, comprising a substrate being arranged on the second layer and being in electrically conductive connection to the recess.

35. The arrangement according to claim 34, comprising the substrate to the second layer being connected via an intermediate layer.

36. The arrangement according to claim 22, comprising the base layer being configured as a carrier plate, the carrier plate comprising a further recess which is adjacent to the channel and filled with electrically conductive material

37. The arrangement according to claim 22, comprising the second layer being fabricated from photo resist.

38. The arrangement according to claim 22, comprising the second layer being fabricated from a plastic material, such as a polymer.

39. A semiconductor arrangement comprising:
a contact layer having a first layer with a channel which is filled with electrically conductive material;
the first layer being disposed on the base layer;
the channel configured as a recess in the first layer;
the recess extending from the upper side of the first layer to the lower side of the first layer; the base layer at least partially covering the channel on a first side of the first layer; and
means for providing a second layer being disposed on a second side of the first layer and partially covering the channel, the second layer comprising a recess which is at least partially arranged above the channel and filled with an electrically conductive material, forming an electrical conductor.
